(19) United States
(12) Patent Application Publication
(10) Pub. No.: US 2002/0155686 A1
(43) Pub. Date: Oct. 24, 2002

(54) Fabrication method for suppressing a hot carrier effect and leakage currents of I/O devices

(76) Inventors: Hung-Sui Lin, Tainan Hsien (TW); Han-Chao Lai, Taichung (TW); Yen-Hung Yeh, Taoyuan (TW); Tao-Cheng Lu, Kaohsiung (TW)

Correspondence Address: POWELL, GOLDSTEIN, FRAZER & MURPHY LLP, P.O. BOX 97223, WASHINGTON, DC, 20090-7223, US

(21) Appl. No.: 09/840,710

(22) Filed: Apr. 24, 2001

(51) Int. Cl. H01L 21/425

(52) U.S. Cl. 438/527; 438/514; 438/530; 438/531; 438/515

(57) ABSTRACT

A method of manufacturing a semiconductor device with a core device and an input/output (I/O) device on a semiconductor substrate has been developed. The semiconductor device, fabricated according to the present method, features the I/O device having graded dopant profiles, obtained from a transient enhanced diffusion effect for suppressing a hot carrier effect, and having pocket/halo implant region for decreasing leakage current.

### FIELD OF THE INVENTION

The present invention relates to a method of fabricating semiconductor devices, and more specifically to semiconductor fabrication processes which result in improvements for suppressing a hot carrier effect and leakage current of input/output devices.

### BACKGROUND OF THE INVENTION

According to the development of deep submicron semiconductor technologies, there is a requirement to reduce sizes of semiconductor devices, while to maintain performance thereof. It is known that the reduction in size results in a problem of a short channel effect. More specifically, the reduction of the channel length causes concentration of an electric field near the junction region, resulting in deterioration of dielectric strength thereof. In addition, hot carriers generated by the concentration of electric field penetrate into the gate oxide films and are trapped therein. As a result, deterioration of semiconductor devices in electrical performance, such as circuit speeds and device reliability, can occur.

In some applications, deep submicron semiconductor technologies are required to offer input/output (I/O) interface compatible with higher operating voltages, for example, 3.3 V. To meet this requirement, a dual gate-oxide process is employed, i.e., a thinner gate oxide for core devices and a thicker gate oxide for I/O devices. Since I/O devices usually share the same substrate architecture as in core devices for minimizing processing costs, hot carrier effects (HCE) become a serious problem especially in the design of I/O devices. That is because hot carrier effects in core devices are relieved by using reduced supply voltage (≦2.0 V), while I/O devices, operating at higher voltages, would encounter performance degradation due to hot carrier effects.

In order to solve the degradation problem of dual gate-oxide devices, resulted from hot carrier effects, after an anneal procedure, an ion implantation with a transient enhanced diffusion (TED) effect will be applied to reduce the peak electric fields in the channels of I/O devices. More specifically, according to the TED effect, more graded dopant profiles are generated to increase the hot carrier resistance of I/O devices. However, graded dopant profiles, obtained from the TED effect, substantially decrease the channel length as well as adversely influence the Off-current. There exists a need for semiconductor devices, especially for deep submicron semiconductor, to reduce the hot carrier effect without increasing the Off-current.

### SUMMARY OF THE INVENTION

It is therefore an object of the present invention to provide a simultaneous fabrication method of a semiconductor device with core devices and I/O devices.

It is another object of the present invention to provide a fabrication method of I/O devices, exhibiting graded dopant profiles, needed for suppressing hot carrier effects.

It is still another object of the present invention to provide a method of fabrication sequences of a semiconductor device, especially for N-type semiconductor devices of the I/O device, after formation of lightly doped source/drain (LDD) regions of the core device, comprising a rapid thermal anneal (RTA) procedure and a proceeding pocket/halo implantation procedure.

The present invention discloses a method of fabrication sequences of a semiconductor device, in which core devices and I/O devices are simultaneously fabricated. More specifically, I/O devices feature graded junction profiles, obtained from a transient enhanced diffusion, for suppressing hot carrier effects, as well as utilize pocket implant for Off-current adjustment. According to the present invention, the foregoing and other objects are achieved in part by a method of manufacturing a semiconductor device, comprising: providing a semiconductor substrate; forming a first gate electrode, electrically isolated from said substrate, on a first region of said semiconductor substrate for said core device, and forming a second gate electrode, electrically isolated from said substrate, on a second region of said semiconductor substrate for said I/O device; using said first gate electrode and said second gate electrode as masks, applying a first lightly doped source/drain implant and a first pocket implant to said core device, and to said I/O device; performing a rapid thermal anneal procedure, to activate lightly doped source/drain regions of said core device; using said second gate electrode as a mask, applying a second LDD implant and a second pocket implant to said I/O device; forming insulator spacers, on the sides of said first gate electrode and on the sides of said second gate electrode; and using said first gate electrode and the insulator spacer of said first gate electrode, and said second gate electrode and the insulator spacer of said second gate electrode as masks, forming deep source/drain regions over said core device and said I/O device.

### BRIEF DESCRIPTION OF THE DRAWINGS

For a more complete understanding of the invention, references are made to the following detailed description of the preferred embodiment taken in connection with the accompanying drawings in which:

FIGS. 1-2 schematically illustrate the fabrication steps of core device regions of the present invention;

FIGS. 2-4 schematically illustrate the fabrication steps of I/O device regions of the present invention; and

FIG. 5 schematically illustrates the preferred embodiment of the present invention.

### DETAILED DESCRIPTION OF THE PREFERRED EMBODIMENT

The method discloses fabrication sequences of a semiconductor device, in which core devices and I/O devices are simultaneously fabricated. A semiconductor device produced in accordance with the present invention exhibits graded junction profiles of I/O devices in dual gate-oxide semiconductor devices. The I/O devices would benefit, in terms of a decreased HCE reliability phenomenon, from graded dopant profiles, obtained from procedures featuring a TED effect.

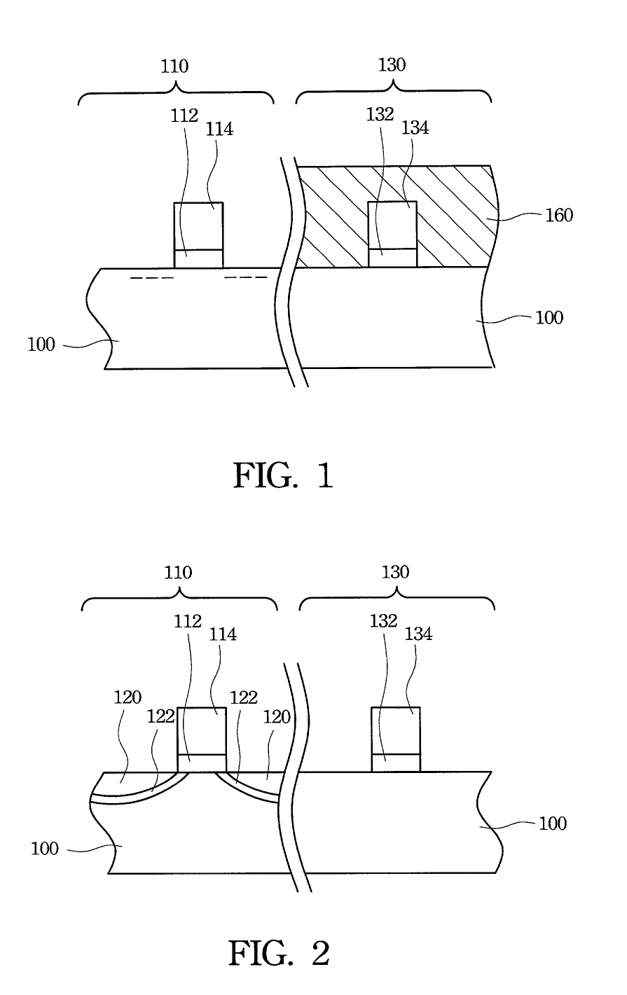

A semiconductor substrate 100, comprised of single crystalline silicon, with a <100> crystallographic orientation, is used and schematically shown in FIG. 1. Region 110, on semiconductor substrate 100, will be used for core device fabrication, while region 130, will be used for fabrication of the I/O devices. As schematically shown in FIG. 1, a first gate electrode 114 with a dielectric layer 112, and a second gate electrode 134 with a dielectric layer 132, are formed on core device region 110, and on I/O device region 130, above semiconductor substrate 100 respectively. Gate electrodes 114 and 134, can be comprised of a doped polysilicon layer, or of a polycide layer, formed by a conventional method such as chemical vapor deposition (CVD) and subsequent etching procedures.

Utilize a photoresist layer 160, patterned on a N-type semiconductor substrate of I/O device region 130, with gate electrodes 114 and 134 as a mask to allow the following ion implantation procedures to be performed in core device region 110 and in a P-type semiconductor substrate of I/O device region 130. For simplicity, FIGS. 1-5 only illustrate the manufacturing method of N-type semiconductor parts of both core device region 110 and I/O device region 130. A first lightly doped source/drain (LDD) implant procedure is then applied to core device region 110 and to I/O device region 130. More specifically, for P-type semiconductor substrates of core device region and to I/O device region (not shown in FIG. 1), the first LDD implant procedure comprises to implant a P-type impurity thereto, which the P-type impurity is selected from a group consisting of boron ion and boron di-fluoride ion. On the other hand, for N-type semiconductor substrates 100 of core device region 110, the first LDD implant procedure further comprises to implant an N-type impurity comprising arsenic ion thereto. Then a first pocket or halo implant procedure for core device region 110 and to I/O device region 130 is proceeding, i.e., for P-type semiconductor substrates of core device region and I/O device region (not shown in FIG. 1). The first pocket implant procedure comprises to implant an N-type impurity thereto, comprising arsenic ion. On the other hand, for N-type semiconductor substrates 100 of core device region 110, the first pocket implant procedure further comprises to implant a P-type impurity selected from a group consisting of boron ion and boron di-fluoride ion thereto.

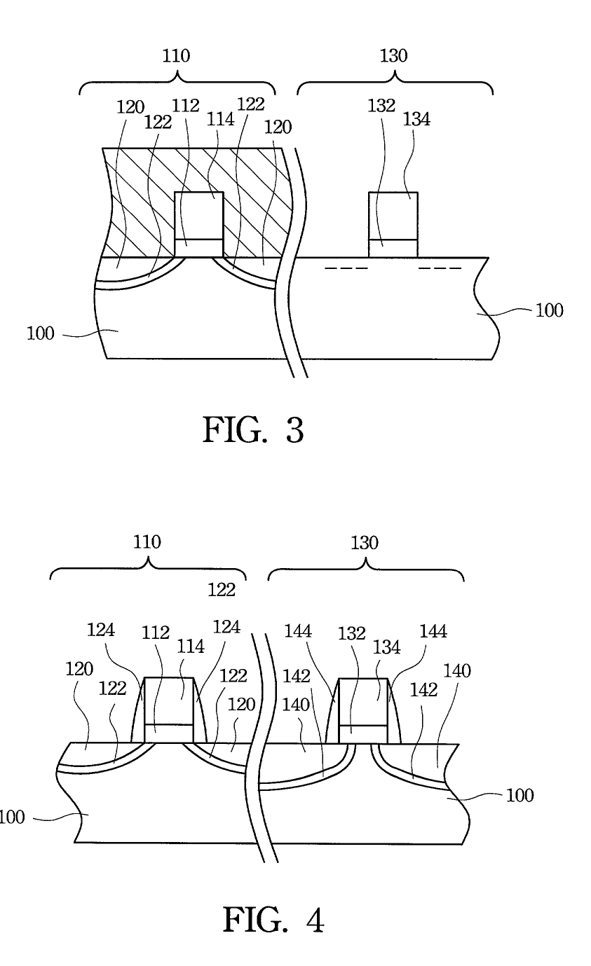

After photoresist layer 160 removal, a rapid thermal anneal (RTA) procedure is performed to activate lightly doped source/drain regions of core device region 110 and I/O device region 130 at a temperature between about 950 to 1100° C., for a time between about 10 to 30 seconds. Accordingly, as shown in FIG. 2, LDD regions 120 and pocket implant regions 122 of core device region 110 are created, while LDD regions 120 exhibit sharp dopant profiles, needed for optimum device performance, and pocket implant regions 122 are designed to reduce short channel effects. Specially, the activating, RTA procedure, sets, or fixes dopant profiles of core devices, therefore subsequent thermal procedures, used for LDD regions of the I/O device, will not change the dopant profiles of LDD regions 120 and pocket implant regions 122 of core device region 110. Although not shown in FIG. 2, LDD regions and pocket implant regions of P-type semiconductor parts of I/O device region 130 are also simultaneously created during the RTA procedure, mentioned above.

As illustrated in FIG. 3, a photoresist layer 170 is next patterned on core device region 110, together with gate electrode 134 used as a mask, to allow the subsequent ion implantation procedures to be performed in N-type semiconductor substrates of I/O device region 130. The subsequent ion implantation procedures comprise a second LDD implant procedure and a second pocket implant procedure for I/O device region 130. More specifically, the second LDD implant procedure comprises to implant a N-type impurity comprising phosphorous ion to N-type semiconductor substrates of I/O device region 130, of an energy between about 60 to 75 KeV, of a dose between about 1E13 atoms/cm² to 5E13 atoms/cm², and of a imparting angle between about 30° to 50°. Meanwhile, the second pocket implant procedure comprises to implant a P-type impurity selected from a group consisting of boron ion and boron di-fluoride ion, to N-type semiconductor substrate of I/O device region 130, of an energy about 45 KeV, of a dose about 1.2E13 atoms/cm², and of a imparting angle about 45°.

After photoresist layer 170 is removed, a subsequent insulator spacer deposition procedure is performed on sides of both first gate electrode 114 and second gate electrode 134. Insulator spacers 124 and 144 are formed from a dielectric layer, comprising a material selected from a group consisting of silicon oxide, silicon nitride, and silicon oxynitride, via a CVD procedure, at a temperature between about 600° C. to 700° C., for a time about 90 minutes. During the subsequent insulator spacer deposition procedure, graded LDD regions 140 and pocket implant regions 142 are therefore formed. More specially, the spacer deposition procedure also provides the TED effect, needed to create graded dopant profiles of LDD regions 140, schematically shown in FIG. 4. The graded dopant profiles of LDD regions 140, is needed to reduce the peak electric fields in the channels of I/O devices, i.e., to reduce the effect of hot electron injection, for I/O devices, which operate at a higher voltage than core devices. It should be noted that graded dopant profiles of LDD regions 140, obtained from the TED effect, feature to suppress the hot carrier effect, but decrease the substantial channel length and thus increase the Off-current. However, according to the present invention, the pocket implant regions 142, created by the second pocket implant procedure and the subsequent spacer deposition procedure, are utilized to adjust the reduction of Off-current by means of parameters control of the second pocket implant procedure, such as changes of energy, angle and concentration of this implant procedure, to substantially optimize the suppression of the hot carrier effect and the decrease of the leakage current. The parameters of the second pocket implant procedure, mentioned above, are only a set of parameters of one preferred embodiment according to the present invention, but not to be construed in a limiting sense.

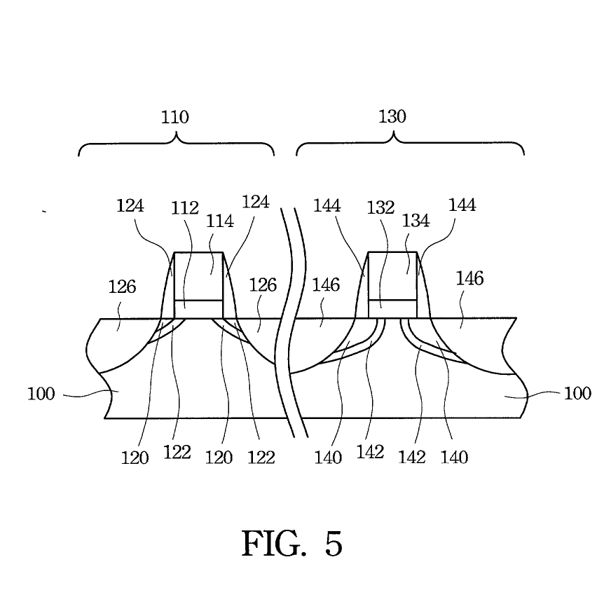

Finally, as schematically shown in FIG. 5, using first gate electrode 114 with insulator spacers 124, and second gate electrode 134 with insulator spacers 144 as masks, deep source/drain regions 126 over core device region 110 and deep source/drain regions 146 over I/O device region 130 are created, via the subsequent standard procedures, such as ion dopant procedures and the proceeding anneal procedure. Ion dopant procedures comprise to implant a N-type impurity comprising arsenic ion to P-type semiconductor substrates of this semiconductor device, and a P-type impurity selected from a group consisting of boron ion and boron di-fluoride ion to N-type semiconductor substrates of the semiconductor device.

Although the invention has been described in detail herein with reference to its preferred embodiment, it is to be understood that this description is by way of example only, and is not to be construed in a limiting sense. It is to be further understood that numerous changes in the details of the embodiments of the invention, and additional embodiments of the invention, will be apparent to, and may be made by, persons of ordinary skill in the art having reference to this description. It is contemplated that such changes and additional embodiments are within the spirit and true scope of the invention as claimed below.

We claim:

1. A method of manufacturing a semiconductor device with a core device and an input/output (I/O) device, comprising the steps of:
providing a semiconductor substrate;
forming a first gate electrode, electrically isolated from said substrate, on a first region of said semiconductor substrate for said core device, and forming a second gate electrode, electrically isolated from said substrate, on a second region of said semiconductor substrate for said I/O device;
using said first gate electrode and said second gate electrode as masks, applying a first lightly doped source/drain (LDD) implant and a first pocket implant to said core device and said I/O device;
performing a rapid thermal anneal (RTA) procedure, to activate lightly doped source/drain regions of said core device;
using said second gate electrode as a mask, applying a second LDD implant and a second pocket implant to said I/O device;
forming insulator spacers on the sides of said first gate electrode and on the sides of said second gate electrode; and
using said first gate electrode and the insulator spacer of said first gate electrode, and said second gate electrode and the insulator spacer of said second gate electrode as masks, forming deep source/drain regions over said core device and said I/O device.

2. The method of claim 1, wherein said first LDD implant further comprises to implant a N-type impurity comprising arsenic ion to a N-type semiconductor substrate of said core device, and a P-type impurity selected from a group consisting of boron ion and boron di-fluoride ion to P-type semiconductor substrates of said core device and said I/O device.

3. The method of claim 1, wherein said first pocket implant further comprises to implant a P-type impurity selected from a group consisting of boron ion and boron di-fluoride ion to said N-type semiconductor substrate of said core device, and an N-type impurity selected from a group consisting of arsenic ion and phosphorous ion to said P-type semiconductor substrates of said core device and said I/O device.

4. The method of claim 1, wherein said RTA procedure is performed at a temperature between about 950 to 1100° C., for a time between about 10 to 30 seconds.

5. The method of claim 1, wherein said second LDD implant further comprises to implant an N-type impurity comprising phosphorous ion to an N-type semiconductor substrate of said I/O device, of an energy between about 60 to 75 KeV, of a dose between about 1E13 atoms/cm² to 5E13 atoms/cm², and of a imparting angle between about 300 to 50°.

6. The method of claim 1, wherein said second pocket implant further comprises to implant a P-type impurity selected from a group consisting of boron ion and boron di-fluoride ion, to said N-type semiconductor substrate of said I/O device, of an energy about 45 KeV, of a dose about 1.2E13 atoms/cm², and of a imparting angle about 45°.

7. The method of claim 1, wherein said insulator spacers are formed from a dielectric layer, comprising a material selected from a group consisting of silicon oxide, silicon nitride, and silicon oxynitride, via a CVD procedure, at a temperature between about 600° C. to 700° C., for a time about 90 minutes.

8. The method of claim 1, wherein forming deep source/ drain regions further comprises to implant an N-type impurity comprising arsenic ion to said P-type semiconductor substrate of said semiconductor device, and a P-type impurity selected from a group consisting of boron ion and boron di-fluoride ion to said N-type semiconductor substrate of said semiconductor device.

9. A method of manufacturing a semiconductor device with a core device and an input/output (I/O) device on a semiconductor substrate, both said core device and said I/O device having a gate electrode, electrically isolated from said semiconductor substrate, comprising the steps of:
performing a rapid thermal anneal (RTA) procedure after first lightly doped source/drain (LDD) regions and first pocket implant regions on said core device and said I/O device have being formed, to activate said first LDD regions;
using the gate electrode of said I/O device as a mask, applying a second LDD implant and a second pocket implant to said I/O device;
forming insulator spacers on the sides of the gate electrodes of said core device and said I/O device; and
using the gate electrodes of said core device and said I/O device as masks, forming deep source/drain regions over said core device and said I/O device.

10. The method of claim 9, wherein said first LDD regions are formed by implanting an N-type impurity comprising arsenic ion to an N-type semiconductor substrate of said core device, and a P-type impurity selected from a group consisting of boron ion and boron di-fluoride ion to P-type semiconductor substrates of said core device and of said I/O device.

11. The method of claim 9, wherein said first pocket implant regions are formed by implanting a P-type impurity selected from a group consisting of boron ion and boron di-fluoride ion to said N-type semiconductor substrate of said core device, and a N-type impurity selected from a group consisting of arsenic ion and phosphorous ion to said P-type semiconductor substrates of said core device and of said I/O device.

12. The method of claim 9, wherein said RTA procedure is performed at a temperature between about 950 to 1100° C., for a time between about 10 to 30 seconds.

13. The method of claim 9, wherein said second LDD implant further comprises to implant a N-type impurity comprising phosphorous ion to a N-type semiconductor substrate of said I/O device, of an energy between about 60 to 75 KeV, of a dose between about 1E13 atoms/cm² to 5E13 atoms/cm², and of a imparting angle between about 300 to 50°.

14. The method of claim 9, wherein said second pocket implant further comprises to implant a P-type impurity selected from a group consisting of boron ion and boron di-fluoride ion, to said N-type semiconductor substrate of said I/O device, of an energy about 45 KeV, of a dose about 1.2E13 atoms/cm², and of a imparting angle about 45°.

15. The method of claim 9, wherein said insulator spacers are formed from a dielectric layer, comprising a material selected from a group consisting of silicon oxide, silicon nitride, and silicon oxynitride, via a CVD procedure, at a temperature between about 600° C. to 700° C., for a time about 90 minutes.

16. The method of claim 9, wherein forming deep source/drain regions further comprises to implant a N-type impurity comprising arsenic ion to said P-type semiconductor substrate of said semiconductor device, and a P-type impurity selected from a group consisting of boron ion and boron di-fluoride ion to said N-type semiconductor substrate of said semiconductor device.
